(19) United States
(12) Patent Application Publication
(10) Pub. No.: US 2024/0146255 A1
(43) Pub. Date: May 2, 2024

(54) AMPLIFIER

(71) Applicant: Sumitomo Electronic Industries, Ltd., Osaka (JP)

(72) Inventor: Takashi SUMIYOSHI, Osaka-shi (JP)

(73) Assignee: Sumitomo Electronic Industries, Ltd., Osaka (JP)

(21) Appl. No.: 18/491,176

(22) Filed: Oct. 20, 2023

(30) Foreign Application Priority Data
Oct. 26, 2022 (JP) 2022-171580

(51) Int. Cl. H03F 1/56; H03F 1/02; H03F 3/60

(52) U.S. Cl. CPC H03F 1/565; H03F 1/0288; H03F 3/602; H03F 2200/423

(57) ABSTRACT

An amplifier includes a first amplifier amplifying first signal, a first matching circuit having first end connected to output node of first amplifier, and second end connected to first intermediate node, and a first transmission line having first end connected to first intermediate node, and second end connected to first output node. At a center frequency of an operating band, a first reactance component of impedance seen from first output node toward first transmission line is smaller than a second reactance component of impedance seen from first intermediate node toward first matching circuit, and at the center frequency, a first characteristic impedance of first transmission line is 0.5 to 2 times an absolute value of first impedance seen from second end of first matching circuit toward first matching circuit when first and second ends of first matching circuit are terminated to reference impedance.

### CROSS REFERENCE TO RELATED APPLICATIONS

This application claims priority based on Japanese Patent Application No. 2022-171580 filed on Oct. 26, 2022, and the entire contents of the Japanese patent application are incorporated herein by reference.

### TECHNICAL FIELD

The present disclosure relates to an amplifier.

### BACKGROUND

In an amplifier for amplifying a high frequency signal such as a microwave signal, a matching circuit is provided between the amplifier and an output terminal. The matching circuit matches a load connected to the output terminal to a desired impedance. That is, when the load is connected to the output terminal, the impedance seen from the amplifier toward the matching circuit becomes the impedance at which the performance of the amplifier can be exhibited. Note that the technique related to the present disclosure is disclosed in International Publication Pamphlet No. WO 2015/093021.

### SUMMARY

An amplifier according to an embodiment of the present disclosure includes a first amplifier amplifying a first signal, a first matching circuit having a first end electrically connected to an output node of the first amplifier, and a second end electrically connected to a first intermediate node, and a first transmission line having a first end electrically connected to the first intermediate node, and a second end electrically connected to a first output node. At a center frequency of an operating band, a first reactance component of an impedance seen from the first output node toward the first transmission line is smaller than a second reactance component of an impedance seen from the first intermediate node toward the first matching circuit. At the center frequency, a first characteristic impedance of the first transmission line is 0.5 to 2 times an absolute value of a first impedance seen from the second end of the first matching circuit toward the first matching circuit when the first end and the second end of the first matching circuit are terminated to a reference impedance.

### BRIEF DESCRIPTION OF THE DRAWINGS

FIG. 1 is a block diagram of an amplifier according to the first embodiment.

FIG. 2 is a block diagram of the amplifier according to the first embodiment.

FIG. 3 is a schematic diagram of a vector of output power in the first embodiment.

FIG. 4 is a schematic diagram of a vector of output power in the first embodiment.

FIG. 5 is a block diagram of the amplifier according to a first comparative example.

FIG. 6 is a flowchart illustrating a method of designing a matching circuit and an offset line in the first embodiment.

FIG. 7 is a block diagram illustrating a load pull measuring system.

FIG. 8 is a Smith chart illustrating an impedance Za1 that is changed by a load pull tuner.

FIG. 9 is a Smith chart illustrating examples of impedances Zsat and Zbo.

FIG. 10 is a circuit diagram for simulating a matching circuit.

FIG. 11 is a circuit diagram for simulating an absolute value of an impedance of a matching circuit.

FIG. 12 is a circuit diagram for simulating an offset line.

FIG. 13 is a Smith chart illustrating an impedance Zo1 after designing a matching circuit and an offset line.

FIG. 14 is a graph illustrating a drain efficiency with respect to an output power in the first embodiment.

FIG. 15 is a block diagram of an amplifier according to the second embodiment.

FIG. 16 is a block diagram of an amplifier according to the third embodiment.

### DETAILED DESCRIPTION

It is difficult to design a matching circuit, and when a reactance component seen from an output terminal toward the matching circuit is large, the desired characteristics cannot be obtained, such as narrowing of the band of the amplifier.

The present disclosure has been made in view of the above problems, and an object of the present disclosure is to provide the amplifier having desired characteristics.

### DESCRIPTION OF EMBODIMENTS OF PRESENT DISCLOSURE

First, the contents of embodiments of the present disclosure will be listed and explained.

(1) An amplifier according to an embodiment of the present disclosure includes a first amplifier amplifying a first signal, a first matching circuit having a first end electrically connected to an output node of the first amplifier, and a second end electrically connected to a first intermediate node and a first transmission line having a first end electrically connected to the first intermediate node, and a second end electrically connected to a first output node. At a center frequency of an operating band, a first reactance component of an impedance seen from the first output node toward the first transmission line is smaller than a second reactance component of an impedance seen from the first intermediate node toward the first matching circuit. At the center frequency, a first characteristic impedance of the first transmission line is 0.5 to 2 times an absolute value of a first impedance seen from the second end of the first matching circuit toward the first matching circuit when the first end and the second end of the first matching circuit are terminated to a reference impedance. This makes it possible to provide an amplifier having desired characteristics.

(2) In the above (1), the first reactance component is 0.5 or less times the second reactance component.

(3) In the above (1) or (2), the first characteristic impedance is 0.8 to 1.25 times the absolute value of the first impedance.

(4) In the above (1), the amplifier further includes a second amplifier amplifying a second signal, a second matching circuit having a first end electrically connected to an output node of the second amplifier, and a second end electrically connected to a second intermediate node, a second transmission line having a first end electrically connected to the second intermediate node, and a second end electrically connected to a second output node, and a combiner combining the amplified first signal output to the first output node and the amplified second signal output to the second output node, and outputting a combined signal as an output signal. At the center frequency, a third reactance component of an impedance seen from the second output node toward the second transmission line is smaller than a fourth reactance component of an impedance seen from the second intermediate node toward the second matching circuit, and at the center frequency, a second characteristic impedance of the second transmission line is 0.5 to 2 times an absolute value of a second impedance seen from the second end of the second matching circuit toward the second matching circuit when the first end and the second end of the second matching circuit are terminated to a reference impedance.

(5) In the above (4), the amplifier further includes a signal processor changing an outphasing angle of the first signal and the second signal, based on an input signal input to the signal processor, outputting the first signal having the changed outphasing angle to the first amplifier, and outputting the second signal having the changed outphasing angle to the second amplifier. The amplifier is an outphasing amplifier.

(6) In the above (5), when the outphasing angle is at least one value between a maximum value and a minimum value, the first reactance component is smaller than the second reactance component and the third reactance component is smaller than the fourth reactance component.

(7) In the above (5), when the outphasing angle is the minimum value, the first reactance component is smaller than the second reactance component and the third reactance component is smaller than the fourth reactance component, and when the outphasing angle is the maximum value, the first reactance component is smaller than the second reactance component and the third reactance component is smaller than the fourth reactance component.

(8) In the above (4), the amplifier further includes a divider dividing an input signal into the first signal and the second signal. The first amplifier is a carrier amplifier, the second amplifier is a peak amplifier, and the amplifier is a Doherty amplifier.

(9) In any one of the above (4) to (8), the first reactance component is ½ or less of the second reactance component, and the third reactance component is ½ or less of the fourth reactance component.

(10) In any one of the above (4) to (8), the first characteristic impedance is 0.8 to 1.25 times the absolute value of the first impedance, and the second characteristic impedance is 0.8 to 1.25 times the absolute value of the second impedance.

### DETAILS OF EMBODIMENTS OF PRESENT DISCLOSURE

Specific examples of amplifiers according to embodiments of the present disclosure will be described below with reference to the drawings. The present disclosure is not limited to these examples, and is defined by the scope of the claims, and is intended to include all modifications within the meaning and scope equivalent to the scope of the claims.

### First Embodiment

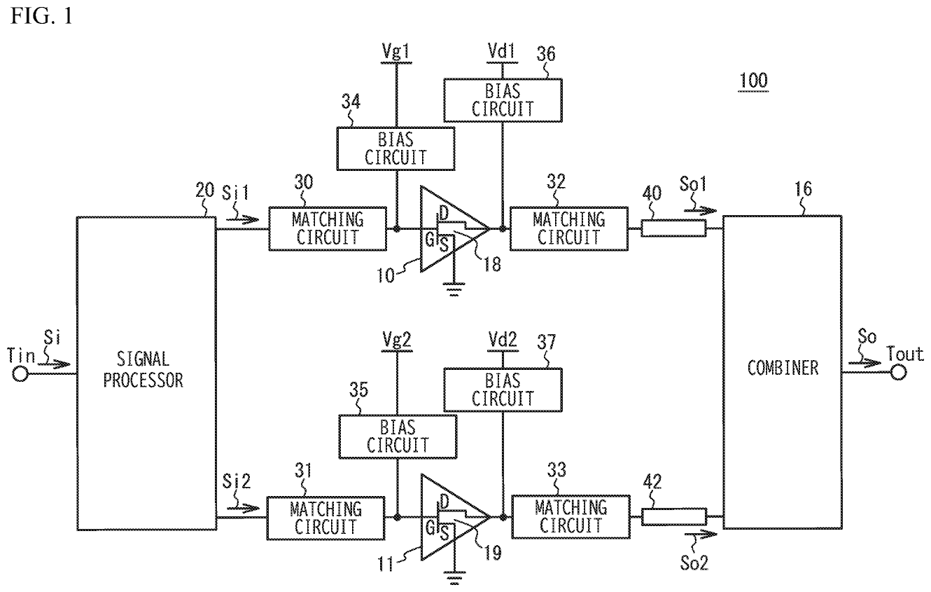

In the first embodiment, an example of an outphasing amplifier will be described as an amplifier. FIG. 1 is a block diagram of an amplifier according to a first embodiment. As illustrated in FIG. 1, in an amplifier 100, an amplifier 10 (first amplifier) and an amplifier 11 (second amplifier) are connected in parallel between an input terminal Tin and an output terminal Tout. A high frequency signal is input to input terminal Tin as an input signal Si. When amplifier 100 is used in mobile communication base stations, the frequency of the high frequency signal is, for example, 0.5 GHz to 10 GHz. A signal processor 20 performs signal processing on input signal Si and outputs two signals Si1 (first signal) and Si2 (second signal).

Signal Si1 passes through a matching circuit 30 and is input to amplifier 10. Matching circuit 30 matches the output impedance of signal processor 20 with the input impedance of amplifier 10. Amplifier 10 amplifies signal Si1 input through matching circuit 30 and outputs the amplified signal So1 through a matching circuit 32 (first matching circuit) and an offset line 40 (first transmission line). Signal So1 passed through matching circuit 32 and offset line 40 is input to a combiner 16. Matching circuit 32 and offset line 40 match the output impedance of amplifier 10 with the input impedance of combiner 16. Signal Si2 passes through a matching circuit 31 and is input to amplifier 11. Matching circuit 31 matches the output impedance of signal processor 20 with the input impedance of amplifier 11. Amplifier 11 amplifies signal Si2 input through matching circuit 31 and outputs the amplified signal So2 through a matching circuit 33 (second matching circuit) and an offset line 42 (second transmission line). Signal So2 passed through matching circuit 33 and offset line 42 is input to combiner 16. Matching circuit 33 and offset line 42 match the output impedance of amplifier 11 with the input impedance of combiner 16. Combiner 16 combines signals So1 and So2. The combined signal is output from output terminal Tout as an output signal So.

A bias circuit 34 supplies a bias voltage Vg1 to a gate G of amplifier 10 and prevents signal Si1 from leaking to the bias terminal. A bias circuit 36 supplies a bias voltage Vd1 to a drain D of amplifier 10 and prevents signal So1 amplified by amplifier 10 from leaking to the bias terminal. A bias circuit 35 supplies a bias voltage Vg2 to gate G of amplifier 11 and prevents signal Si2 from leaking to the bias terminal. A bias circuit 37 supplies a bias voltage Vd2 to drain D of amplifier 11 and prevents signal So2 amplified by amplifier 11 from leaking to the bias terminal.

Amplifiers 10 and 11 include, for example, Field Effect Transistors (FETs) 18 and 19, respectively. Sources S of FETs 18 and 19 are grounded, signals Si1 and Si2 are input to gates G through matching circuits 30 and 31, respectively, and the amplified signals are output from drains D. FETs 18 and 19 are, for example, Gallium Nitride High Electron Mobility Transistor (GaN HEMT) or Laterally Diffused Metal Oxide Semiconductor (LDMOS). Each of amplifiers 10 and 11 may be provided with a multistage FET. The functions of matching circuit 32 and offset line 40, and matching circuit 33 and offset line 42 will be described later.

Signal processor 20 is, for example, a Signal Processing Unit, and digitally processes input signal Si to output signals Si1 and Si2. Amplifier 100, which is an outphasing amplifier, outputs output signal So having the amplitude of the output power corresponding to the amplitude of the input power of input signal Si. Signal processor 20 sets the outphasing angles of signals Si1 and Si2 depending on the amplitude of input signal Si in order to output signal So depending on the amplitude of the input signal Si.

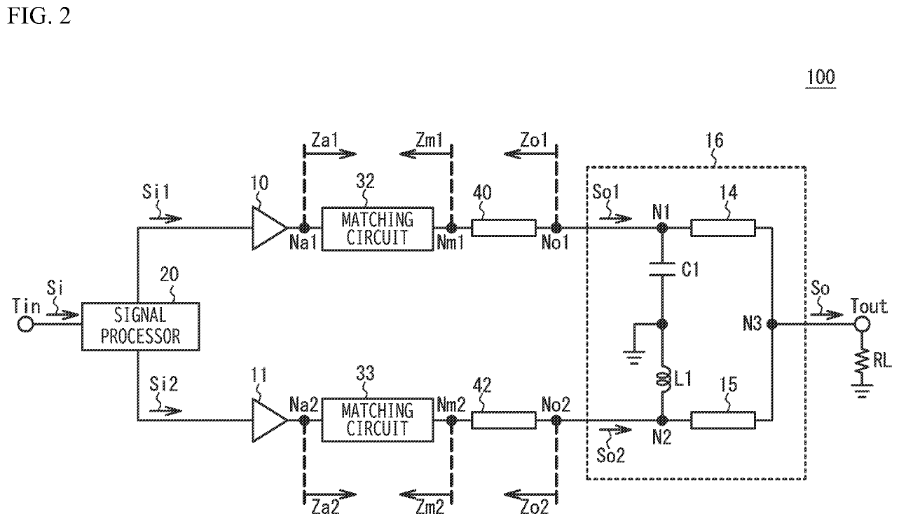

FIG. 2 is a block diagram of the amplifier according to the first embodiment. In FIG. 2, compared to FIG. 1, matching circuits 30 and 31 and bias circuits 34, 35, 36 and 37 are omitted and the internal configuration of combiner 16 is illustrated. As illustrated in FIG. 2, in the outphasing amplifier of the first embodiment, combiner 16 is, for example, a Chireix combiner. Combiner 16 includes an inductor L1, a capacitor C1, and impedance converters 14 and 15. Capacitor C1 is shunt-connected to a node N1 through which signal So1 passes. Inductor L1 is shunt-connected to a node N2 through which signal So2 passes.

The output node of amplifier 10 is a node Na1. A first end of matching circuit 32 is electrically connected to node Na1, and a second end of matching circuit 32 is electrically connected to a node Nm1 (first intermediate node). A first end of offset line 40 is electrically connected to node Nm1, and a second end of offset line 40 is electrically connected to a node No1 (first output node). The output node of amplifier 11 is a node Na2. A first end of matching circuit 33 is electrically connected to node Na2, and a second end of matching circuit 33 is electrically connected to a node Nm2 (second intermediate node). A first end of offset line 42 is electrically connected to node Nm2, and a second end of offset line 42 is electrically connected to a node No2 (second output node).

A load resistor RL is connected to output terminal Tout.

A first end and a second end of load resistor RL are connected to output terminal Tout and the ground, respectively. Impedances seen from nodes Na1 and Na2 toward matching circuits 32 and 33 are load impedances Za1 and Za2 of amplifiers 10 and 11, respectively. An impedance seen from node No1 toward offset line 40 is a first impedance Zo1. An impedance seen from node No2 toward offset line 42 is a third impedance Zo2. An impedance seen from node Nm1 toward matching circuit 32 is a second impedance Zm1. An impedance seen from node Nm2 toward matching circuit 33 is a fourth impedance Zm2. Impedances Zo1, Zo2, Zm1 and Zm2 are Ro1+jXo1, Ro2+jXo2, Rm1+jXm1 and Rm2+jXm2, respectively. Ro1, Ro2, Rm1 and Rm2 are real parts and resistance components. Xo1, Xo2, Xm1 and Xm2 are imaginary parts and reactance components. The “j” is an imaginary unit.

First ends of impedance converters 14 and 15 are connected to nodes N1 and N2, respectively, and second ends thereof are commonly connected to a node N3. Signal So1 and signal So2 are combined at node N3. Impedance converters 14 and 15 convert the output impedances of offset lines 40 and 42 into resistance values twice load resistor RL, respectively. As a result, an impedance seen from output terminal Tout toward node N3 becomes the resistance value of load resistor RL. Impedance converters 14 and 15 are, for example, transmission lines having an electrical length of approximately λ/4. The “λ” is the wavelength at the center frequency of the operating frequency band of amplifier 100. The electrical length of impedance converters 14 and 15 is, for example, 3λ/16 to 5λ/16 or 7λ/32 to 9λ/32.

[Description of Outphasing Operation]

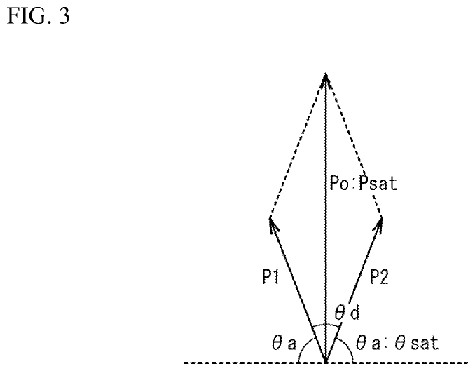

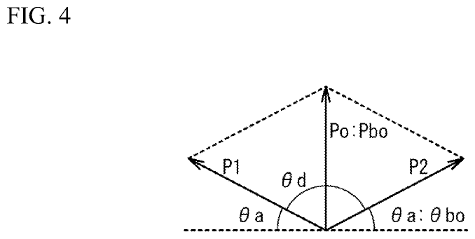

FIG. 3 and FIG. 4 are schematic diagrams of vectors of output power in the first embodiment. FIG. 3 corresponds to a case where an output power Po of amplifier 100 is maximized, and FIG. 4 corresponds to a case where an output power Po of amplifier 100 is minimized. Maximum output power Po is referred to as the saturation power and is represented by a power Psat. Minimum output power Po is referred to as back-off power and is represented by a power Pbo. A difference between power Psat and power Pbo is a dynamic range.

In FIGS. 3 and 4, a power P1 is a vector of the power of signal So1 at an output node No1, and a power P2 is a vector of the power of signal So2 at an output node No2. Powers P1 and P2 are, for example, saturation powers of amplifiers 10 and 11, respectively. A composite vector of powers P1 and P2 is output power Po output from output terminal Tout. When the outphasing angle is θa and the phase difference between powers P1 and P2 is θd, then 2×θa+θd=180°. That is, when the phase of electric power P1 is rotated by +θa and the phase of electric power P2 is rotated by −θa from the state where the phase difference θd is 180°, the angle θa is referred to as the outphasing angle.

As illustrated in FIG. 3, when output power Po is increased, an outphasing angle θa is increased to approach 90°. As illustrated in FIG. 4, when output power Po is decreased, outphasing angle θa is decreased to approach 0°. In combiner 16 which is a Chireix combiner, when the outphasing angle is set to around 900 and around 0°, the reactance components of the impedances seen from output nodes No1 and No2 toward combiner 16 increase, and load impedances Za1 and Za2 of amplifiers 10 and 11 deviate from the optimum values. Therefore, outphasing angle θa is used in a range between an angle θsat smaller than 90° and an angle θbo larger than 0°. That is, in FIG. 3, when output power Po is power Psat, outphasing angle θa is angle θsat. In FIG. 4, when output power Po is power Pbo, outphasing angle θa is angle θbo. Angle θsat is, for example, 70°, and angle θbo is, for example, 10°.

Outphasing angle θa is controlled by signal processor 20. For example, when output power Po is increased, signal processor 20 increases outphasing angles θa of signals Si1 and Si2. When output power Po is decreased, signal processor 20 decreases outphasing angles θa of signals Si1 and Si2. Outphasing angles θa of signals Si1 and Si2 are substantially the same as outphasing angles θa of signals So1 and So2 obtained by amplifying signals Si1 and Si2. Therefore, signal processor 20 changes outphasing angles θa of signals Si1 and Si2, so that outphasing angles θa of signals So1 and So2 can be changed. As described above, signal processor 20 changes outphasing angles θa of signals Si1 and Si2 based on input signal Si to be input, and outputs signals Si1 and Si2 having the changed outphasing angle θa to amplifiers 10 and 11.

Load resistor RL of FIG. 2 is dependent on outphasing angle θa. When outphasing angle θa is angle θsat, the resistance value of load resistor RL is a resistance value Rsat, and when outphasing angle θa is angle θbo, the resistance value of load resistor RL is a resistance value Rbo which is larger than resistance value Rsat. Resistance values Rsat and Rbo are, for example, 11Ω and 88Ω, respectively. As described above, in the outphasing amplifier, the difference between the resistance values of load resistors RL increases, and for example, resistance value Rbo is, for example, twice or more resistance value Rsat.

### Comparative Example 1

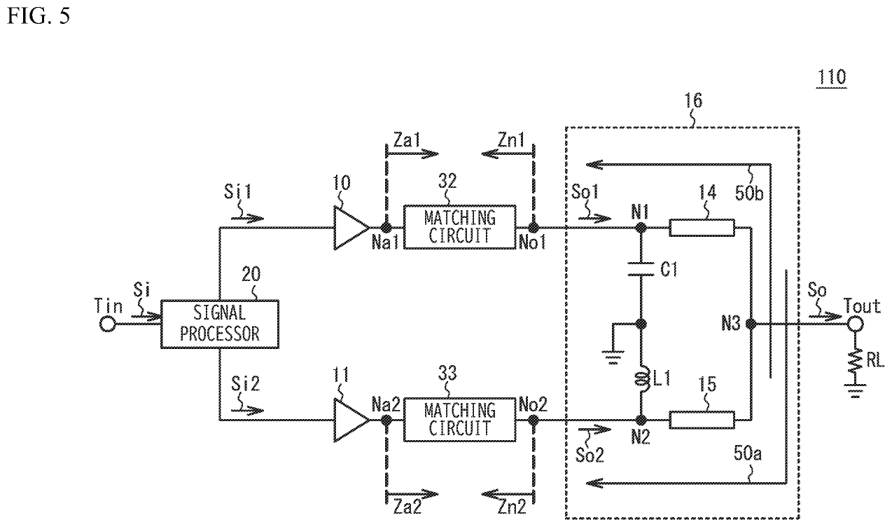

FIG. 5 is a block diagram of an amplifier according to a first comparative example. As illustrated in FIG. 5, in an amplifier 110 of the first comparative example, offset lines 40 and 42 are not provided. The other circuit configuration is the same as that of FIG. 2 of the first embodiment.

The problem of first comparative example will be described. Since the dynamic range of the outphasing amplifier is large, the difference between resistance values Rsat and Rbo of load resistor RL is large. Matching circuit 32 (and 33) is designed so that load impedance Za1 (and Za2) seen from node Na1 (and Na2) toward matching circuit 32 (and 33) causes the performance of amplifier 10 to approach an optimum value even if load resistor RL changes. For example, matching circuit 32 (and 33) is designed such that impedance Za1 (and Za2) maximizes the performance such as the drain efficiency of amplifier 10 (and 11) when the resistance value of load resistor RL is resistance value Rsat, and impedance Za1 (and Za2) maximizes the performance such as the drain efficiency of amplifier 10 (and 11) when the resistance value of load resistor RL is resistance value Rbo.

However, as indicated by an arrow 50a, a part of signal So1 passes over node N3 and wraps around to output node No2. Similarly, as indicated by an arrow 50b, a part of signal So2 passes over node N3 and wraps around to output node No1. This complicates the design of matching circuits 32 and 33. One reason for this is that reactance components Xn1 and Xn2 of impedances Zn1 and Zn2 seen from output nodes No1 and No2 toward matching circuits 32 and 33 respectively, are large.

When reactance components Xn1 and Xn2 of impedance Zn1 and Zn2 are small, the circuit design subsequent to nodes No1 and No2 can be performed by converting the impedances on the real axis of the Smith chart, and the design is relatively easy. For example, when a λ/4 line is used, impedance conversion on the real axis becomes easy. However, when the reactance components of impedances Zn1 and Zn2 are large, it is not easy to design a circuit subsequent to nodes No1 and No2. Especially in outphasing amplifiers, matching circuits 32 and 33, combiner 16, and the like are designed and the wraparounds of signals So1 and So2 such as arrows 50a and 50b are taken into consideration, so that impedances Za1 and Za2 become optimum at resistance values Rsat and Rbo of load resistor RL.

As described above, in the first comparative example, since reactance components Xn1 and Xn2 of impedance Zn1 and Zn2 are large, it is difficult to design amplifier 110. In addition, the expected characteristics of the amplifier at the time of design differ from the actual characteristics of the amplifier.

Further, when reactance components Xn1 and Xn2 of impedance Zn1 and Zn2 are large, the Q values (Quality factor) of matching circuits 32 and 33 become high. Therefore, the band of the frequency becomes narrow.

[Method of Designing Matching Circuit and Offset Line in First Embodiment]

A method of designing matching circuits 32 and 33 and offset lines 40 and 42 according to the first embodiment will be described. In the following description, the method of designing matching circuit 32 and offset line 40 will be mainly described, but the same applies to the method of designing matching circuit 33 and offset line 42.

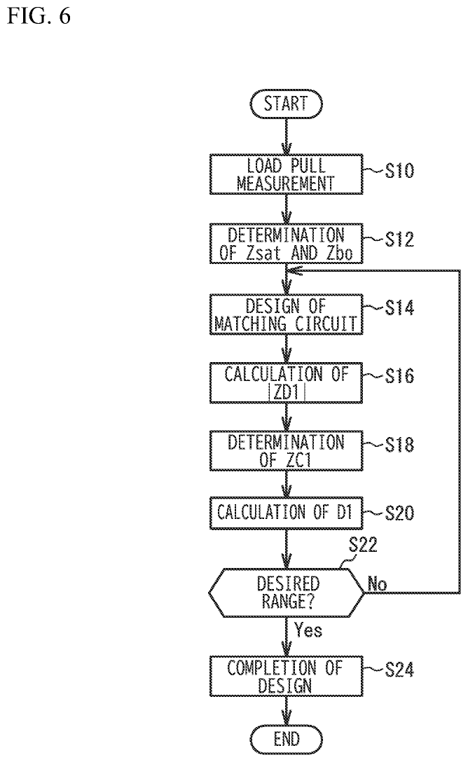

FIG. 6 is a flowchart illustrating a method of designing a matching circuit and an offset line according to the first embodiment. As illustrated in FIG. 6, first, load pull measurement of amplifier 10 is performed (step S10).

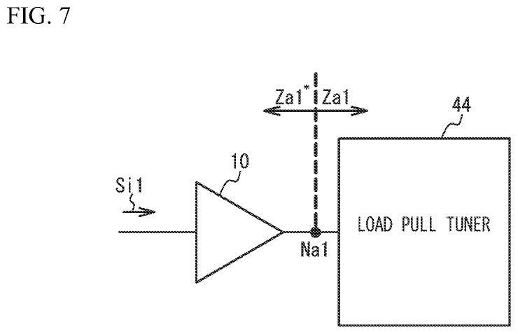

FIG. 7 is a block diagram illustrating a load pull measuring system. As illustrated in FIG. 7, an output node Na1 of amplifier 10 is connected to a load pull tuner 44. Signal Si1 which is a high frequency signal of a center frequency f0 (for example, 3.5 GHz) of an operating band of amplifier 100 is input to amplifier 10. A Bias voltage (for example, a gate bias voltage and a drain bias voltage) applied to amplifier 10 is set to a voltage at the time of operation. In this state, load pull tuner 44 changes impedance Za1 seen from node Na1 toward load pull tuner 44.

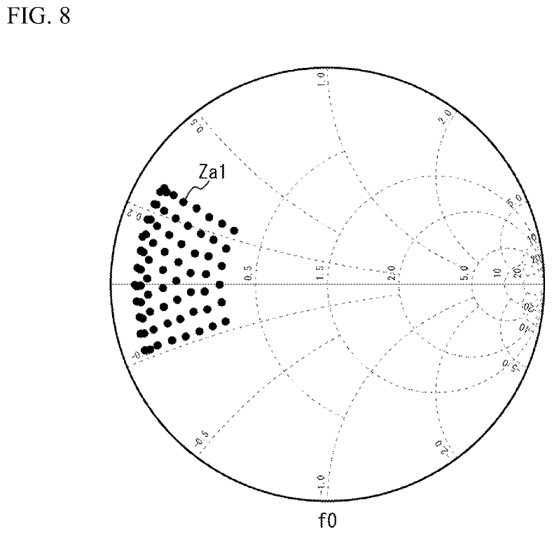

FIG. 8 is a Smith chart illustrating an impedance Za1 that is changed by the load pull tuner. Each of dots in FIG. 8 indicates impedance Za1 set by load pull tuner 44. As illustrated in FIG. 8, load pull tuner 44 changes impedance Za1 on the Smith chart. Load pull tuner 44 measures high frequency characteristics such as gain and drain efficiency of amplifier 10 at each point of the changed impedance Za1.

Returning to FIG. 6, impedances Zsat and Zbo are determined as impedances Za1 when output power Po of amplifier 100 is powers Psat and Pbo (i.e., load resistor RL is resistance values Rsat and Rbo), respectively (step S12). Impedances Zsat and Zbo are set to be different load impedances. For example, impedance Zsat is determined by giving priority to the output power of amplifier 10 being equal to or more than a desired value and the drain efficiency not becoming low. Impedance Zbo is determined by giving priority to the output power of amplifier 10 becoming a desired value and the drain efficiency becoming high.

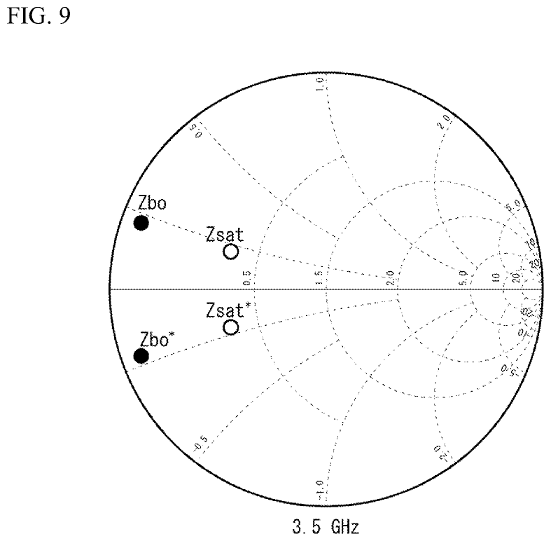

FIG. 9 is a Smith chart illustrating examples of impedances Zsat and Zbo. FIG. 9 illustrates an example of impedances Zsat and Zbo in the outphasing amplifier in which GaN HEMTs are used as FETs 18 and 19 and center frequency f0 is 3.5 GHz. Output power Po when outphasing angle θa is 700 is defined as power Psat. At this time, resistance value Rsat is 11Ω. Output power Po when outphasing angle θa is 10° is defined as power Pbo. At this time, resistance value Rbo is 88Ω.

Impedances Zsat and Zbo in FIG. 9 are the load impedances at which the drain efficiency is optimal when the respective output powers Po are powers Psat and Pbo. When amplifier 10 operates at the maximum drain efficiency or the like, the impedance seen from node Na1 toward amplifier 10 is impedances Zsat* and Zbo* when the respective output power Po is power Psat and Pbo. Impedances Zsat and Zsat* are complex conjugates, and impedances Zbo and Zbo* are complex conjugates.

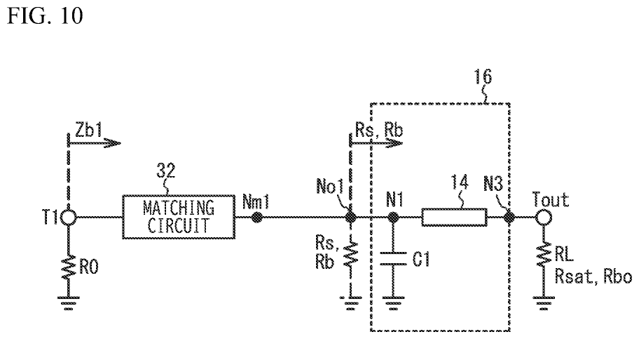

Returning to FIG. 6, matching circuit 32 is designed by simulation (step S14). FIG. 10 is a circuit diagram for simulating the matching circuit. As illustrated in FIG. 10, a terminal T1 is terminated to a reference impedance R0 (e.g., 50Ω). That is, the first end of reference impedance R0 is connected to terminal T1, and the second end is connected to the ground. The circuit from matching circuit 32 to load resistor RL is a circuit obtained by extracting the circuit from node Na1 to load resistor RL in the first comparative example of FIG. 5. The first end and the second end of matching circuit 32 are connected to terminal T1 and node Nm1, respectively. The offset line is not connected between nodes Nm1 and No1. In combiner 16, node No1 is connected to node N1. Capacitor C1 is shunt-connected to node N1. The first end and the second end of impedance converter 14 are connected to nodes N1 and N3, respectively. In the simulation, each impedance (substantially resistance values Rs and Rb since the reactance components are small) seen from node No1 toward combiner 16 when load resistor RL is set to resistance values Rsat and Rbo, is used. In this case, the circuit in FIG. 10 is equivalent to a circuit in which node No1 is terminated by resistance values Rs and Rb, as indicated by a dashed line.

When load resistor RL is set to resistance value Rsat, that is, when node No1 is terminated by resistance value Rs, an impedance Zb1 seen from terminal T1 toward matching circuit 32 becomes impedance Zsat. When load resistor RL is set to resistance value Rbo, that is, when node No1 is terminated by resistance value Rb, impedance Zb1 seen from terminal T1 toward matching circuit 32 becomes impedance Zbo. Matching circuit 32 that satisfies the above condition is calculated by simulation. Matching circuit 32 can be realized by combining at least one of a distributed constant line, a stub, a capacitor, and an inductor. As an example, two distributed constant elements are connected in series between terminal T1 and node Nm1 as matching circuit 32. The prestage distributed constant element has a characteristic impedance of 68Ω at 3.5 GHz and rotates the phase by 10°. The poststage distributed constant element has a characteristic impedance of 22.3Ω at 3.5 GHz and rotates the phase by 158°. As a result, matching circuit 32 satisfying the above condition can be designed.

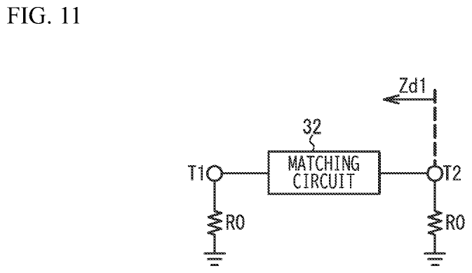

Returning to FIG. 6, an absolute value |Zd1| of an impedance Zd1 of matching circuit 32 is calculated (step S16). FIG. 11 is a circuit diagram for simulating an absolute value of impedance of matching circuit 32. As illustrated in FIG. 11, the first end and the second end of matching circuit 32 designed in step S14 are connected to terminals T1 and T2, respectively. Terminals T1 and T2 are terminated by reference impedance R0 (50Ω as an example). At this time, impedance Zd1 seen from terminal T2 toward matching circuit 32 is calculated by simulation. Impedance Zd1 is a complex number, and the absolute value |Zd11 of impedance Zd1 is calculated. When Zd1=Rd1+jXd1 (Rd1 is a resistance component, Xd1 is a reactance component, and j is an imaginary unit) is satisfied, |Zd1|=√(Rd1²+Xd1²) is satisfied.

Returning to FIG. 6, the absolute value |Zd1| calculated in step S16 is determined as a first characteristic impedance Zc1 of offset line 40 (step S18). Offset line 40 is a transmission line, such as a microstrip line or a coplanar line.

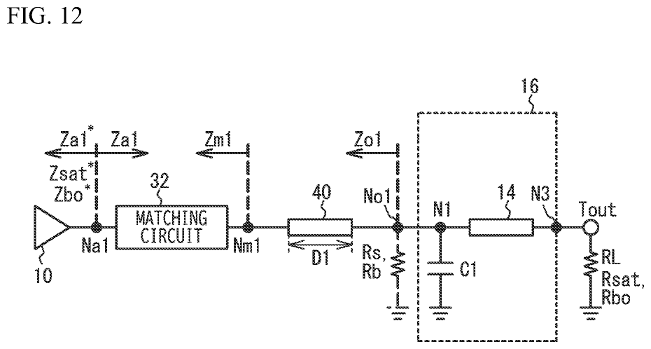

A length D1 of offset line 40 is calculated or determined (step S20). FIG. 12 is a circuit diagram for simulating the offset line. As illustrated in FIG. 12, the first end of matching circuit 32 is connected to output node Na1 of amplifier 10. The first end and the second end of offset line 40 are connected to nodes Nm1 and No1, respectively. Other connection relations are the same as those in FIG. 10, and the descriptions thereof are omitted. Similarly to FIG. 10, when load resistor RL has resistance values Rsat and Rbo, the simulation is performed on the assumption that resistors having resistance values Rs and Rb are shunt-connected to node No1 as indicated by the dashed line.

First, the case where output power Po is Psat is considered. In the simulation, it is assumed that a resistor having resistance value Rs is shunt-connected at node No1. Impedance Za1* seen from node Na1 toward amplifier 10 is virtually set to impedance Zsat*. That is, it is assumed that amplifier 10 is operating in a state in which output power Po becomes a saturation power Psat. When length D1 of offset line 40 is set to 0, second impedance Zm1 seen from node Nm1 toward matching circuit 32 is equal to first impedance Zo1 seen from node No1 toward matching circuit 32, and a reactance component Xm1 of second impedance Zm1 is large.

This is because matching circuit 32 is designed by terminating terminal T1 by reference impedance R0 in step S14 as illustrated in FIG. 10. That is, in the state of FIG. 10, the impedance seen from node No1 toward matching circuit 32 is substantially equal to resistance value Rs, and there is substantially no reactance component. However, since the prestage impedance of matching circuit 32 is changed from reference impedance R0 to impedance Zsat*, reactance component Xm1 of impedance Zm1 increases. The reason why matching circuit 32 is designed by using the circuit in which terminal T1 is terminated by the reference impedance as illustrated in FIG. 10 is that it is difficult to design (simulate) matching circuit 32 with impedance Za1* seen from matching circuit 32 toward the prestage as impedance Zsat* as illustrated in FIG. 12.

Assuming that characteristic impedance Zc1 of offset line 40 is an absolute value |Zd11, impedance Za1 seen from node Na1 toward 32 is hardly changed even if length D1 of offset line 40 is changed. Thus, when load resistor RL is resistance value Rsat, impedance Za1 is substantially impedance Zsat even if length D1 is changed. On the other hand, when length D1 of offset line 40 is changed, impedance Zo1 seen from node No1 toward matching circuit 32 rotates on the Smith chart.

Next, the case where output power Po is power Pbo is considered. In the simulation, it is assumed that a resistor of resistance value Rb is shunt-connected at node No1. Impedance Za1* seen from node Na1 toward amplifier 10 is virtually set to impedance Zbo*. The first characteristic impedance of offset line 40 is |Zc1|. Therefore, even if length D1 is changed, impedance Za1 is substantially impedance Zbo. On the other hand, when length D1 of offset line 40 is changed, impedance Zo1 rotates on the Smith chart.

When output power Po is Psat, impedance Zo1 seen from node No1 toward offset line 40 is defined as impedance Zo1s, and when output power Po is power Pbo, impedance Zo1 seen from node No1 toward offset line 40 is defined as impedance Zo1b. Length D1 of offset line 40 is changed to search for length D1 at which both impedances Zo1s and Zo1b are closest to the real axis. Length D1 when both impedances Zo1s and Zo1b are closest to the real axis is calculated.

Returning to FIG. 6, when length D1 of offset line 40 is calculated in step S20 (step S22), it is determined whether a reactance component Xo1s of impedance Zo1s and a reactance component Xo1b of impedance Zo1b are within the desired range. In the desired range, for example, the absolute value of reactance component Xo1s may be the desired value or less and the absolute value of reactance component Xo1b may be the desired value or less. In addition, in the desired range, an average (for example, a simple average or a geometric average) of the absolute value of reactance component Xo1s and the absolute value of reactance component Xo1b may be the desired value or less. When step S22 is No, that is, when reactance components Xo1s and Xo1b are not within the desired range, the process returns to step S14 to design matching circuit 32 again. Thereafter, steps S16, S18 and S20 are performed. When step S22 is Yes, the design of matching circuit 32 and offset line 40 is completed (step S24). Thereafter, the process ends.

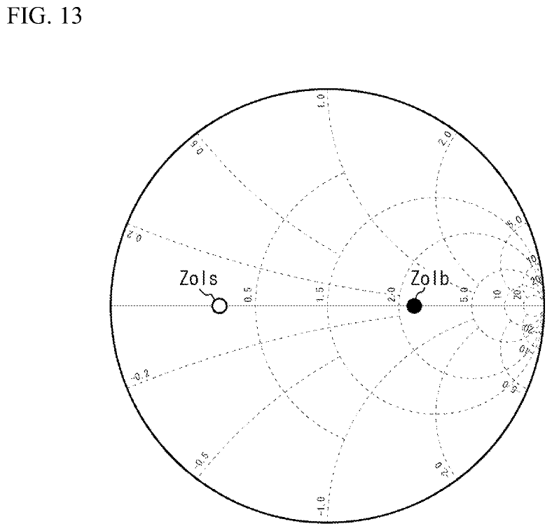

FIG. 13 is a Smith chart illustrating impedance Zo1 after designing matching circuit 32 and offset line 40. As illustrated in FIG. 13, both impedances Zo1s and Zo1b are located substantially on the real axis, and reactance components Xo1s and Xo1b are substantially 0.

When matching circuit 32 and offset line 40 of which the design is completed are used, both impedances Zo1s and Zo1b in FIG. 13 have small reactance components Xo1s and Xo1b and are substantially on the real axis of the Smith chart. For impedance to be matched at node No1, impedances Zo1s and Zo1b are approximately resistance values Rs and Rb. When impedances Zo1s and Zo1b are on the real axis, the impedances can be easily converted by using an impedance converter using a λ/4 line.

Matching circuit 33 and offset line 42 are designed in the same manner as matching circuit 32 and offset line 40. That is, a second characteristic impedance Zc2 of offset line 42 is set to the absolute value |Zd2| of an impedance Zd2 of matching circuit 33, and the length of offset line 42 is calculated so that a reactance component Xo2 of impedance Zo2 becomes small.

When matching circuits 32 and 33 and offset lines 40 and 42 are designed using the above design method, amplifier 100 including matching circuits 32 and 33 and combiner 16 can be easily designed even when a part of signal So1 wraps around to node No2 as illustrated by arrow 50a in the first comparative example of FIG. 5 and a part of signal So2 wraps around to node No1 as illustrated by arrow 50b, because reactance components Xo1 and Xo2 of impedances Zo1 and Zo2 of seen from noes No1 and No2 toward offset lines 40 and 42 respectively are small when output power Po is power Psat and power Pbo. For this reason, the expected characteristics of amplifier 100 at the time of design and the actual characteristics of amplifier 100 can be substantially matched. Further, since the reactance components of impedances Zo1s and Zo1b are small, the Q values of matching circuit 32 and offset line 40 and the Q values of matching circuit 33 and offset line 42 can be reduced. Therefore, the band of amplifier 100 can be widened.

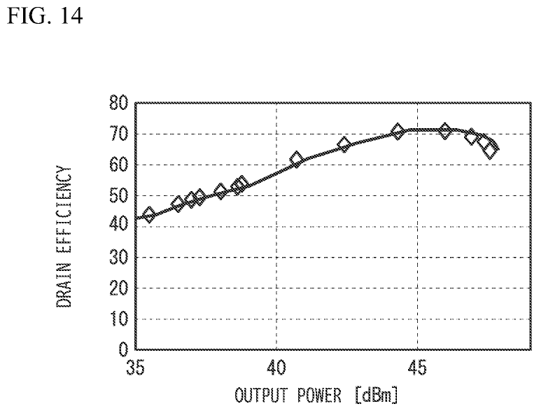

FIG. 14 is a graph illustrating drain efficiency with respect to an output power in the first embodiment. In FIG. 14, diamond-shaped dots are simulation results and solid lines are measurement results of actual amplifier. GaN HEMTs were used as FETs 18 and 19. Center frequency f0 of the operating band is 3.5 GHz. Impedances Za1 and Za2 are impedances Zsat and Zbo illustrated in FIG. 9. Impedances Zo1 and Zo2 are impedances Zo1s and Zo1b illustrated in FIG. 13. The two distributed constant elements described in step S14 were used as matching circuits 32 and 33. Characteristic impedances Zc1 and Zc2 of offset lines 40 and 42 are 18Ω. Length D1 of offset lines 40 and 42 corresponds to 1060 as the phase at 3.5 GHz. As illustrated in FIG. 14, the simulation result matches well with the measurement result. As described above, by using the above-described design method, the expected characteristics of the amplifier at the time of design and the actual characteristics of the amplifier can be substantially matched.

According to the first embodiment, at center frequency f0 of the operating band of amplifier 100, first characteristic impedance Zc1 (and second characteristic impedance Zc2) of offset line 40 (and 42) is set to the absolute value |Zd1| (and |Zd2|) of first impedance Zd1 (and third impedance Zd2) seen from the second end of matching circuit 32 (and 33) toward matching circuit 32 (and 33) when the first end and the second end of matching circuit 32 (and 33) are terminated by the reference impedance. Accordingly, length D1 of offset line 40 (and 42) hardly affects impedance Za1 (and Za2), and first reactance component Xo1 (and third reactance component Xo2) of impedance Zo1 (and Zo2) can be made substantially 0. This facilitates the design of matching circuits 32 and 33, combiner 16, and the like. In addition, the operating band of amplifier 100 can be widened.

At center frequency f0, first characteristic impedance Zc1 (and second characteristic impedance Zc2) of offset line 40 (and 42) may be 0.5 to 2 times the absolute value |Zd1| (and |Zd2|) of first impedance Zd1 (and second impedance Zd2) seen from the second end of matching circuit 32 (and 33) toward matching circuit 32 (and 33) when the first end and the second end of matching circuit 32 (and 33) are terminated by the reference impedance. Accordingly, even when length D1 of offset line 40 (and 42) is changed, impedance Za1 (and Za2) is hardly changed, and the phase of impedance Zo1 (and Zo2) can be rotated to reduce first reactance component Xo1 (and third reactance component Xo2) of impedance Zo1 (and Zo2).

First characteristic impedance Zel (and second characteristic impedance Zc2) of offset line 40 (and 42) may be 0.8 to 1.25 times, 0.9 to 1.1 times, or 0.95 to 1.05 times the absolute value |Zd1| (and |Zd2|) of first impedance Zd1 (and second impedance Zd2) of matching circuit 32 (and 33).

First reactance component Xo1 (and third reactance component Xo2) of impedance Zo1 (and Zo2) may be smaller than second reactance component Xm1 (and fourth reactance component Zm2) of impedance Zm1 (and Xm2). First reactance component Xo1 (and third reactance component Xo2) may be 0.5 or less times, 0.2 or less times, or 0.1 or less times second reactance component Xm1 (fourth reactance component Xm2).

In the outphasing amplifier, since the resistance value of load resistor RL greatly changes, it is difficult to design matching circuits 32 and 33 and combiner 16. In addition, since signal So1 wraps around to node No2 and signal So2 wraps around to node No1, the design of matching circuits 32 and 33 becomes more difficult. Therefore, as in the first embodiment, offset lines 40 and 42 are provided to reduce reactance components Xo1 and Xo2 of impedances Zo1 and Zo2, thereby facilitating the design of amplifier 100.

Reactance components Xo1, Xo2, Xm1 and Xm2 may satisfy the above condition when outphasing angle θa is at least one value between the maximum value (angle θsat) and the minimum value (angle θbo).

Furthermore, when outphasing angle θa is both the maximum value (angle θsat) and the minimum value (angle θbo) (that is, when output power Po is both power Psat and power Pbo), reactance components Xo1, Xo2, Xm1, and Xm2 satisfy the above condition. This facilitates optimizing the performance of amplifiers 10 and 11 when output power Po is both power Psat and power Pbo.

### Second Embodiment

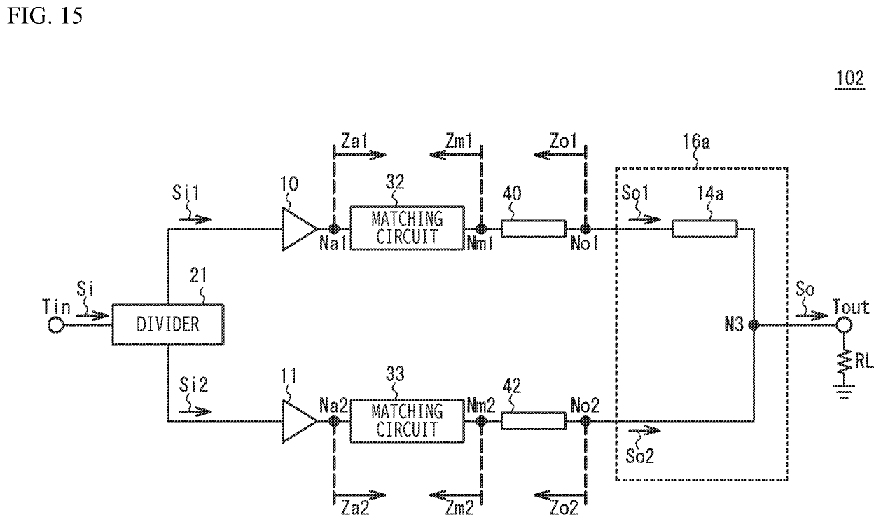

A second embodiment is an example of a Doherty amplifier as an amplifier. FIG. 15 is a block diagram of the amplifier according to the second embodiment. Illustration of Matching circuits 30 and 31 and bias circuits 34 to 37 is omitted. As illustrated in FIG. 15, in an amplifier 102 of the second embodiment, amplifier 10 which is a carrier amplifier and amplifier 11 which is a peak amplifier are connected in parallel between input terminal Tin and output terminal Tout. A high frequency signal is input to input terminal Tin as input signal Si. A divider 21 divides input signal Si input to input terminal Tin into two signals Si1 and Si2. Divider 21 is for example a Wilkinson-type divider.

Amplifier 10 amplifies signal Si1, and outputs the amplified signal So1 to node No1 through matching circuit 32 and offset line 40. Amplifier 11 amplifies signal Si2 and outputs the amplified signal So2 to node No2 through matching circuit 33 and offset line 42. A combiner 16a includes an impedance converter 14a and node N3. Impedance converter 14a is, for example, a λ/4 line, and converts impedance. Signals So1 and So2 are combined at node N3 and output from output terminal Tout as output signal So. Other configurations are the same as those of the first embodiment, and a description thereof is omitted.

Amplifier 10 operates in class AB or class B, and amplifier 11 operates in class C. When the input power is small, amplifier 10 mainly amplifies the input signal. When the input power increases, amplifier 11 amplifies the peak of the input signal in addition to amplifier 10. Thus, amplifiers 10 and 11 amplify the input signal. When the input power is small and amplifier 11 is off, the impedance seen from node No1 toward node N3 is twice (for example, 100Ω) the resistance value of load resistor RL of output terminal Tout. When the input power increases and amplifier 11 operates, the impedance seen from nodes No1 and No2 toward node N3 is the resistance value (for example, 50Ω) of load resistor RL of output terminal Tout.

Matching circuit 32 is designed such that, when amplifier 11 is off, impedance Za1 seen from output node Na1 of amplifier 10 toward matching circuit 32 causes the performance of amplifier 10 to be an optimum value (for example, the drain efficiency becomes maximum at the saturation power). Matching circuit 32 is designed such that, when amplifier 11 is on, impedance Za1 causes the performance of amplifier 10 to be the optimum value. That is, matching circuit 32 is designed such that amplifier 10 operates optimally with impedance Za1 when the impedance seen from node No1 to node N3 is RL and 2×RL.

Matching circuit 33 is designed such that, when amplifier 11 is on, impedance Za2 causes the performance of amplifier 11 to be the optimum value (for example, the drain efficiency becomes maximum at the saturation power). Further, matching circuit 33 is designed such that, when amplifier 11 is off, the impedance of matching circuit 33 seen from node N3 becomes infinite.

As in the second embodiment, even in the case of the Doherty amplifier, matching circuits 32 and 33 are designed such that amplifiers 10 and 11 operate optimally under the condition that the impedances (resistance value) seen from node No1 toward load resistor RL are different. Further, signal So1 wraps around to node No2, and signal So2 wraps around to node No1. Therefore, the design of amplifier 102 including matching circuits 32 and 33, combiner 16a and so on is complicated. Therefore, as in the first embodiment, offset lines 40 and 42 are provided to reduce the reactance components of impedances Zo1 and Zo2. This facilitates the design of amplifier 102.

Not only in the case of the outphasing amplifier and the Doherty amplifier, but also in the case where a plurality of amplifiers 10 and 11 connected in parallel are provided and combiner 16 or 16a for combining signals output from the plurality of amplifiers 10 and 11 is provided, signal So1 wraps around to node No2 and signal So2 wraps around to node No1. Therefore, it is difficult to design the amplifier. Therefore, by providing offset lines 40 and 42, the amplifier can be easily designed.

Although two sets of amplifiers 10 (and 11), matching circuits 32 (and 33), and offset lines 40 (and 42) have been described in the first and second embodiments, three or more sets of amplifiers, matching circuits, and offset lines may be provided.

### Third Embodiment

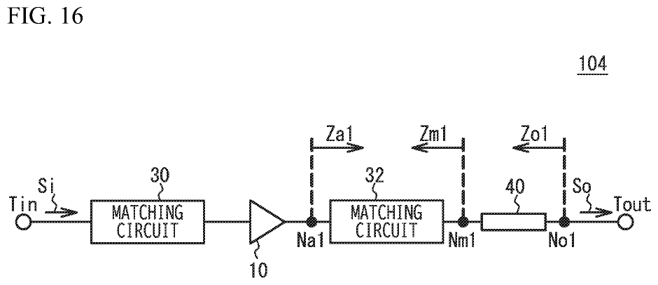

FIG. 16 is a block diagram of an amplifier according to a third embodiment. Illustration of the bias circuit is omitted. As illustrated in FIG. 16, in an amplifier 104 of the third embodiment, input signal Si input from input terminal Tin is input to amplifier 10 via matching circuit 30. Amplifier 10 amplifies input signal Si and outputs the amplified output signal So to output terminal Tout via matching circuit 32 and offset line 40.

As in the third embodiment, one set of amplifier 10, matching circuit 32, and offset line 40 may be provided. Even in this case, characteristic impedance Zc1 of offset line 40 is set to 0.5 to 2 times the absolute value |Zd1| of impedance Zd1 of matching circuit 32. Reactance component Xo1 of impedance Zo1 is made smaller than reactance component Xm1 of impedance Zm1. As a result, the Q value becomes small and the operating band can be widened.

It should be understood that the embodiments disclosed herein have been presented for the purpose of illustration but not limited in all respects. It is intended that the scope of the present disclosure is not limited to the description above but defined by the scope of claims, and encompasses all modifications equivalent in the meaning and scope to the claims.

What is claimed is:

1. An amplifier comprising:
a first amplifier amplifying a first signal;
a first matching circuit having a first end electrically connected to an output node of the first amplifier, and a second end electrically connected to a first intermediate node; and
a first transmission line having a first end electrically connected to the first intermediate node, and a second end electrically connected to a first output node,
wherein at a center frequency of an operating band, a first reactance component of an impedance seen from the first output node toward the first transmission line is smaller than a second reactance component of an impedance seen from the first intermediate node toward the first matching circuit, and
at the center frequency, a first characteristic impedance of the first transmission line is 0.5 to 2 times an absolute value of a first impedance seen from the second end of the first matching circuit toward the first matching circuit when the first end and the second end of the first matching circuit are terminated to a reference impedance.

2. The amplifier according to claim 1, wherein
the first reactance component is 0.5 or less times the second reactance component.

3. The amplifier according to claim 1, wherein
the first characteristic impedance is 0.8 to 1.25 times the absolute value of the first impedance.

4. The amplifier according to claim 1, further comprising:
a second amplifier amplifying a second signal;
a second matching circuit having a first end electrically connected to an output node of the second amplifier, and a second end electrically connected to a second intermediate node;
a second transmission line having a first end electrically connected to the second intermediate node, and a second end electrically connected to a second output node; and
a combiner combining the amplified first signal output to the first output node and the amplified second signal output to the second output node, and outputting a combined signal as an output signal,
wherein at the center frequency, a third reactance component of an impedance seen from the second output node toward the second transmission line is smaller than a fourth reactance component of an impedance seen from the second intermediate node toward the second matching circuit, and
at the center frequency, a second characteristic impedance of the second transmission line is 0.5 to 2 times an absolute value of a second impedance seen from the second end of the second matching circuit toward the second matching circuit when the first end and the second end of the second matching circuit are terminated to a reference impedance.

5. The amplifier according to claim 4, further comprising:
a signal processor changing an outphasing angle of the first signal and the second signal, based on an input signal input to the signal processor, outputting the first signal having the changed outphasing angle to the first amplifier, and outputting the second signal having the changed outphasing angle to the second amplifier,
wherein the amplifier is an outphasing amplifier.

6. The amplifier according to claim 5, wherein
when the outphasing angle is at least one value between a maximum value and a minimum value, the first reactance component is smaller than the second reactance component and the third reactance component is smaller than the fourth reactance component.

7. The amplifier according to claim 5, wherein
when the outphasing angle is the minimum value, the first reactance component is smaller than the second reactance component and the third reactance component is smaller than the fourth reactance component, and
when the outphasing angle is the maximum value, the first reactance component is smaller than the second reactance component and the third reactance component is smaller than the fourth reactance component.

8. The amplifier according to claim 4, further comprising:
a divider dividing an input signal into the first signal and the second signal,
wherein the first amplifier is a carrier amplifier, the second amplifier is a peak amplifier, and the amplifier is a Doherty amplifier.

9. The amplifier according to claim 4, wherein
the first reactance component is ½ or less of the second reactance component, and
the third reactance component is ½ or less of the fourth reactance component.

10. The amplifier according to claim 4, wherein
the first characteristic impedance is 0.8 to 1.25 times the absolute value of the first impedance, and
the second characteristic impedance is 0.8 to 1.25 times the absolute value of the second impedance.
